(19) United States
(12) Patent Application Publication
(10) Pub. No.: US 2006/0218459 A1
(43) Pub. Date: Sep. 28, 2006

(54) Coding systems and methods

(76) Inventor: David Hedberg, Menlo Park, CA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/433,599

(22) Filed: May 12, 2006

Related U.S. Application Data
(63) Continuation-in-part of application No. 11/203,617, filed on Aug. 12, 2005.
(60) Provisional application No. 60/601,556, filed on Aug. 13, 2004.
(60) Provisional application No. 60/681,114, filed on May 13, 2005.

(51) Int. Cl. H03M 13/00

(52) U.S. Cl. 714/752

(57) ABSTRACT

Disclosed herein are various embodiments of coding systems and methods. In one method embodiment, among others, a coding method comprises receiving input parameters, and providing a packet comprising variable FEC code block sizes throughout the packet structure based on the input parameters.

### CROSS-REFERENCE TO RELATED APPLICATION

This application is a continuation-in-part of copending U.S. utility application entitled, “Systems and Methods of Decreasing Latency in a Digital Transmission System,” having Ser. No. 11/203,617, filed Aug. 12, 2005, which claims the benefit of U.S. Provisional Application No. 60/601,556, filed Aug. 12, 2004, which are both entirely incorporated herein by reference.

This application claims priority to copending U.S. provisional application having Ser. No. 60/681,114, filed May 13, 2005, which is entirely incorporated herein by reference.

### 1. FIELD OF THE INVENTION

The present invention is generally related to digital communications and, more particularly, is related to systems and methods for advanced block forward-error-correction (FEC) encoding and decoding of digital communications.

### 2. RELATED ART

Communication networks come in a variety of forms. Notable networks include wireline and wireless. Wireline networks include local area networks (LANs), DSL networks, and cable networks, among others. Wireless networks include cellular telephone networks, classic land mobile radio networks and satellite transmission networks, among others. These wireless networks are typically characterized as wide area networks. More recently, wireless local area networks and wireless home networks have been proposed, and standards, such as Bluetooth and IEEE 802.11, have been introduced to govern the development of wireless equipment for such localized networks.

A wireless local area network (LAN) typically uses infrared (IR) or radio frequency (RF) communications channels to communicate between portable or mobile computer terminals and stationary access points or base stations. These access points are, in turn, connected by a wired or wireless communications channel to a network infrastructure which connects groups of access points together to form the LAN, including, optionally, one or more host computer systems.

Wireless protocols such as Bluetooth and IEEE 802.11 support the logical interconnections of such portable roaming terminals having a variety of types of communication capabilities to host computers. The logical interconnections are based upon an infrastructure in which at least some of the terminals are capable of communicating with at least two of the access points when located within a predetermined range, each terminal being normally associated, and in communication, with a single one of the access points. Based on the overall spatial layout, response time, and loading requirements of the network, different networking schemes and communication protocols have been designed so as to most efficiently regulate the communications.

IEEE Standard 802.11 (“802.11”) is set out in “Wireless LAN Medium Access Control (MAC) and Physical Layer (PHY) Specifications” and is available from the IEEE Standards Department, Piscataway, N.J. 802.11 permits either IR or RF communications at 1 Mbps, 2 Mbps and higher data rates, a medium access technique similar to carrier sense multiple access/collision avoidance (CSMA/CA), a power-save mode for battery-operated mobile stations, seamless roaming in a full cellular network, high throughput operation, diverse antenna systems designed to eliminate “dead spots,” and an easy interface to existing network infrastructures. The IEEE Standard 802.11b extension supports data rates up to 11 Mbps.

The 802.11a standard defines data rates of 6, 12, 18, 24, 36 and 54 Mbps in the 5 GHz band. Demand for higher data rates may result in the need for devices that can communicate with each other at the higher rates, yet co-exist in the same WLAN environment or area without significant interference or interruption from each other, regardless of whether the higher data rate devices can communicate with the 802.11a devices. It may further be desired that high data rate devices be able to communicate with the 802.11a devices, such as at any of the standard 802.11a rates.

One challenge in designing a wireless transmission system is the channel coding method. One coding method uses low density parity check codes (LDPCCs). LDPCCs are block codes with long block lengths. Performance advantages are derived by virtue of the long block length and code structures, which allow soft iterative decoding to aid decoding decision convergence. Error rate performance improves with increases in block length and the number of decoding iterations performed.

A block code has parameters (n,k) where n is the block length (# bits) and k is the number of information bits encoded per block. Traditional block encoders add a fixed number of parity bits, m=n−k, to each block of k information bits to form an n bit encoded block with code rate R=k/n.

For typical LDPC codes of interest, the decoder generally uses a large degree of parallelism to perform a desired number of decoding iterations on each received soft codeword. Thus, the upper limit of decoding speed is governed approximately by the product of the maximum average coded transmission rate, the number of parity bits per block (1−R), and the number of decoding iterations performed per block. To keep the bit error rate performance (or more appropriately the code block error rate performance) approximately constant across the packet, the codewords in a packet structure are of approximately equal size, equal rate, and are subject to an equal number of decoding iterations. Otherwise the weakest code block in the packet tends to dominate the overall packet error rate.

Another challenge for a decoder in a WLAN radio is to be able to promptly complete the decoding at the end of reception of a packet so that a return acknowledgement can be immediately sent back to the transmitter. WLAN radios rely on an “ARQ” mechanism to communicate packet errors and instigate retransmission of the packet in the event of an error. The minimum time allowed for this varies according to the utilized standard, but can be as short as 6 us or so for next generation 802.11 radios. The time between end of reception and the transmission of an acknowledgement is “dead” airtime and thus contributes to network overhead. Therefore, the minimum interframe transmission time (SIFs) for acknowledgement is optimized in the standard to be as short as possible within practical constraints.

### 3. SUMMARY

This disclosure describes systems and methods for advanced block forward-error-correction (FEC) encoding and decoding of packets in a digital communication system. In one embodiment, among others, a coding method comprises receiving input parameters, and providing a packet comprising variable forward error-correction (FEC) code block sizes throughout the packet structure based on the input parameters.

Other systems, methods, features and advantages of the disclosure will be or will become apparent to one with skill in the art upon examination of the following figures and detailed description. It is intended that all such additional systems, methods, features and advantages be included within this description, be within the scope of the invention, and be protected by the accompanying claims.

### 4. BRIEF DESCRIPTION OF THE DRAWINGS

The components in the figures are not necessarily to scale, emphasis instead being placed upon illustrating the principles of the disclosed systems and methods. In the figures, like reference numerals designate corresponding parts throughout the different views.

FIG. 1 is a block diagram that illustrates a PHY layer operation.

FIG. 2 is a block diagram of an exemplary physical layer convergence procedure protocol data unit (PPDU) packet structure generated by the PHY layer of FIG. 1.

FIG. 3 is a functional block diagram of an embodiment of a coding system as implemented in an exemplary communications environment.

FIG. 4 is a block diagram that illustrates an embodiment of a PPDU encoder of the coding system shown in FIG. 3.

FIGS. 5A-5F are block diagrams that illustrate an exemplary fitting or merging process performed by the PPDU encoder of FIG. 4.

FIGS. 6A-6C are block diagrams that illustrate fitting or merging considerations for tail sequences by the PPDU encoder of FIG. 4.

FIG. 7 is a schematic diagram that illustrates an exemplary mechanism used by the PPDU encoder of FIG. 4 in selecting a tail sequence.

FIG. 8 is a schematic diagram that illustrates exemplary performance features of the encoder of FIG. 4.

FIG. 9 is a flow diagram of a coding method embodiment.

FIG. 10 is a flow diagram of a coding method embodiment.

### 5. DETAILED DESCRIPTION

Disclosed herein are various embodiments of coding systems and methods (herein, simply coding systems or coding system for brevity). The coding systems of the preferred embodiments comprise advanced forward error correction (FEC) coding features using low density parity check (LDPC) codes. Low density parity check codes are block codes with long block length that are used for encoding a data signal prior to modulation and transmission. LDPC codes derive performance advantages by virtue of the long block length and code structure, which enable soft iterative decoding to aid decoding decision convergence. Error rate performance generally improves with increases in block length and the number of decoding iterations performed. The coding systems of the preferred embodiments optimize a plurality of performance parameters in communication systems, such as wireless LAN applications. For instance, such coding systems may encode packet data by maximizing the block size and minimizing the rate. One embodiment of the coding systems achieves this optimization by adapting input parameters (e.g., transmission parameters, such as the target transmission load and packet length provided by a media access controller or MAC) of coding blocks and the number of symbols used for transmission. Such input parameters may be based on various factors, including amplification, amount of data to be transmitted, capabilities of the transmitter, receiver and/or network, conditions of the link, etc.

Coding systems of the preferred embodiments are herein described in the context of a new proposed standard, referred to as IEEE 802.1 n (the “802.1 In proposal”), which is a high data rate extension of the 802.11a standard at 5 GHz. It is noted that, at the present time, the 802.11 n proposal is only a draft standard and is not yet a completely defined standard. However, one having ordinary skill in the art would understand that other applicable standards include Bluetooth, xDSL, other sections of 802.11, etc.

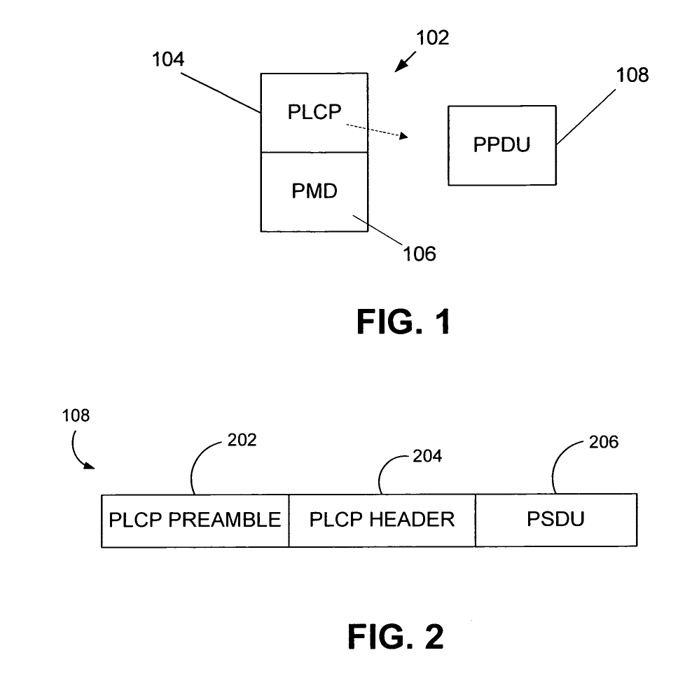

802.11 is directed to wireless LANs, and in particular specifies the MAC and the PHY layers. These layers are intended to correspond closely to the two lowest layers (i.e., the data link layer and the physical layer) of a system based on the ISO Basic Reference Model of OSI. The PHY layer is responsible for encoding and decoding data into signals that are transmitted across a particular medium. FIG. 1 is a block diagram that illustrates a high level view of frame preparation for transmission of data in an 802.11 compliant system. As provided in FIG. 1, a PHY layer 102 includes Physical Layer Convergence Procedure (PLCP) sublayer 104 and Physical Medium Dependent (PMD) sublayer 106. The PLCP sublayer 104 prepares 802.11 frames for transmission and directs the PMD sublayer 106 to actually transmit signals, change radio channels, receive signals, etc. The PLCP sublayer 104 takes each 802.11 frame that is to be transmitted and forms PLCP protocol data unit (PPDU) 108.

FIG. 2 comprises an example packet structure for the PPDU 108 shown in FIG. 1. The PPDU comprises a PLCP preamble 202, a PLCP header 204, and a physical layer service data unit (PSDU) 206. The PSDU 206 represents the contents of the PPDU 108 (i.e., the actual 802.11 frame being sent).

The PPDU 108 and, specifically, the PSDU field 206, comprise the basic packet data units when a data frame is being transmitted. A “payload” is the data size (e.g., in bytes) that a packet will carry. Depending on input parameters such as modulation and coding rates selected for transmission, the amount of coded data that is packed into the orthogonal frequency division multiplexing (OFDM) frame may vary.

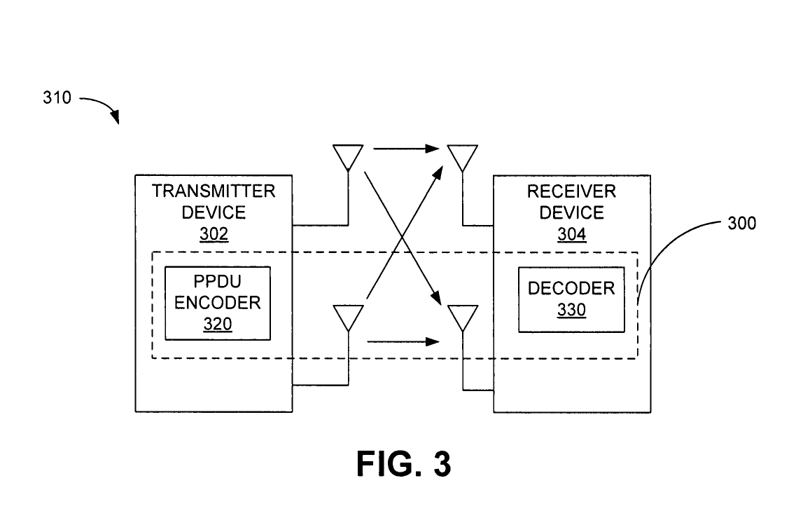

Having described conceptually the mechanisms involved in packet construction for transmission in 802.11 compliant systems, embodiments of coding systems at the PHY layer are now addressed in the context of a communications environment. Note that although the disclosed coding system embodiments are described as being implemented in the PHY layer, one having ordinary skill in the art would understand, in the context of this disclosure, that at least a portion of the coding system functionality described herein may be employed in the MAC layer in some embodiments. FIG. 3 is a functional block diagram that illustrates an embodiment of a coding system 300 as implemented in a multiple-input multiple-output (MIMO) orthogonal frequency division multiplexing (OFDM) communication system 310. The coding system 300 implements PPDU encoding with LDPCC FEC encoding, and decoding. The MIMO communication system 310 comprises a transmitter device 302 communicatively coupled to a receiver device 304. In some embodiments, the transmitter device 302 may comprise functionality of the receiver device 304, and the receiver device 304 may comprise functionality of the transmitter device 302.

The coding system 300 comprises various logic for performing PPDU encoding and decoding. In one embodiment, the coding system comprises a PPDU encoder 320 (also referred to herein as encoding logic) in the transmitter device 302 and a decoder 330 (also referred to herein as decoding logic) in the receiver device 304. One having ordinary skill in the art would appreciate that in some embodiments the transmitter device 302 may comprise decoding functionality of the decoder 330 (such as in transceiver embodiments), and likewise, the receiver device 304 may comprise encoding functionality of the PPDU encoder 320. Note that in some embodiments, the decoder 330 may comprise FEC decoding functionality, which is the inverse of the FEC encoding functionality implemented at the transmitter device 302, or such FEC decoding functionality may be performed at a different decoding device. In one embodiment, the PPDU encoder 320 comprises PPDU encoding functionality as described below, and FEC encoding functionality (e.g., functionality to perform block channel encoding of information bits once the codeword structure parameters have been determined by the PPDU encoder processing described below). In some embodiments, FEC encoding functionality may be performed by a device separate from the device that performs PPDU encoding functionality. The PPDU encoding process is generally distinguished from the FEC encoding process that is driven by the PPDU encoding parameters. That is, the PPDU encoding process typically creates the parameters or recipe upon which FEC encoding operates to block encode the data. Further, one having ordinary skill in the art would understand in the context of this disclosure that the coding system 300 may be embodied in many wireless communication devices, including computers (desktop, portable, laptop, etc.), consumer electronic devices (e.g., multi-media players), compatible telecommunication devices, personal digital assistants (PDAs), or any other type of network devices, such as printers, fax machines, scanners, hubs, switches, routers, set-top boxes, televisions with communication capability, etc.

The transmitter device 302 and receiver device 304 each comprise radio circuitry and one or more antennas. In general, the transmitter device 302 comprises functionality to encode (e.g., via PPDU encoder 320) and interleave incoming data and map the interleaved data into respective subcarrier channels as frequency domain symbols. The transmitter device 302 may also include further processing functionality corresponding to the insertion of training signals, cyclic extensions (e.g., guard intervals), inverse fast Fourier transformation (IFFT), and wave shaping. The processed subcarriers are modulated, filtered, and amplified, and then transmitted via one or more antennas.

The receiver device 304 generally comprises one or more antennas to receive the transmitted data, and may further include downconversion, signal separation, and/or other processing that complements the processing performed at the transmitter device 302. Additional functionality may include timing recovery, cyclic extension removal, transformation (e.g., fast Fourier transformation or FFT), demapping, deinterleaving, and decoding functionality (as provided by the decoder 330).

In general, prior to a transmission, the media access controller (MAC) defines input parameters such as the number of payload bytes and the desired modulation, coding, and rate parameters for the transmission. Then the PPDU encoder 320 determines the actual packet construction parameters to use for the designated (PPDU) transmission. Packets are composed, transmitted, received, and decoded independently with FEC codewords and OFDM symbol structures that may be different for each packet.

The coding system 300 can be implemented using digital circuitry, analog circuitry, or a combination of both. Also, the coding system 300 can be implemented in hardware, software, firmware, or a combination thereof. If implemented in hardware, the coding system 300 can be implemented with any or a combination of the following technologies, which are all well known in the art: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

If implemented partly or wholly in software, the coding system 300 or portions thereof can be comprised of software or firmware that is stored in a memory and that is executed by a suitable instruction execution system.

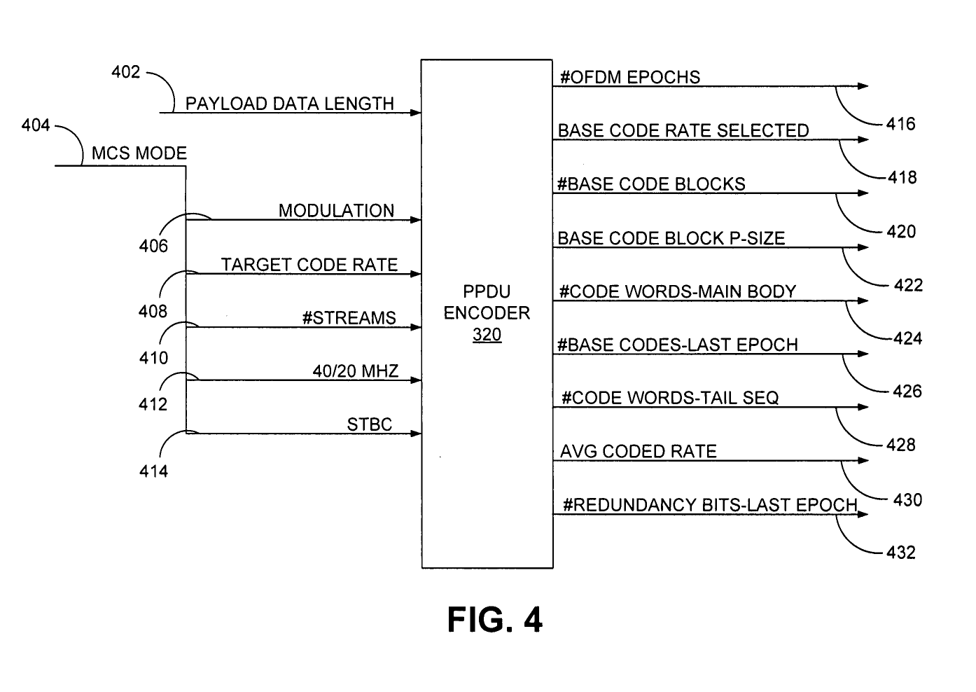

Referring to FIG. 4, shown is an embodiment of the PPDU encoder 320 and an illustration of the various inputs and outputs corresponding to the PPDU encoder 320. Although emphasis is directed herein to the PPDU encoder 320 of coding system 300, one having ordinary skill in the art would understand in the context of this disclosure that the decoder 330 implements the inverse processing of the encoder 320 and thus discussion of the decoder functionality is abbreviated herein. The input parameters determined by the MAC and passed to the PHY layer encoder 320 include payload data length 402 (packet length) and modulation and coding scheme (MCS) 404, which includes modulation rate and transmission mode information. The MCS 404 comprises information corresponding to required modulation 406, target code rate 408, number (#) of streams 410, channel bandwidth (40/20 MHz) 412, and a space-time block code (STBC) option 414. The STBC option 414 is generally applied to signals being transmitted simultaneously on multiple antennas. In one embodiment, the PPDU encoder 320 requires that the number of OFDM symbols be an even number when the STBC option 414 is utilized (to be transmitted alternately on different antennas).

The PPDU encoder 320 receives one or more of these input parameters and generates a plurality of output parameters (shown on the right-had side of the diagram of FIG. 4). The output parameters comprise number of OFDM epochs 416, base code rate selected 418, number of base code blocks 420, base code block puncture (p) size 422, number of codewords in the main body 424, number of base codes in the last epoch 426, number of codewords in the tail sequence 428, average (avg) coded rate 430, and number of redundancy bits in the last epoch 432. Although most if not all of these parameters are self-explanatory, further discussion is directed to a few of these parameters below. With regard to base code rate selected 418, the basic coding rates targeted in next generation WLAN standards may include, for example, ½, ⅔, ¾, and/or ⅚. When a packet is to be transmitted, the MAC decides the modulation mode (e.g., modulation 406) and which of these basic rates to target (e.g., target code rate 408) in the transmission. The target code rate 408 is viewed as an upper bound for the actual rate used after PPDU encoding the data into a packet. The code performance improves with lower rates (because there are more parity bits per information bit). So the PPDU encoding performed by the PPDU encoder 320 ensures that data is encoded at least as reliably as it would be with the selected basic rate, R (target code rate selected 408). Due to encoded data frame constraints, the actual transmission rate, therefore, is less than or equal to R.

With regard to the number of base code blocks 420, the 802.11 draft standard allows one of three code block sizes (e.g., 648, 1296, 1944, or similarly, since 648×1=648, 648×2=1296, and 648×3=1944, x1, x2, and x3 respectively), the selection of which depends on the capabilities of the PPDU encoder 320. The longest block (1944 or x3) corresponds to the highest performance, and thus is the preferred block size for use in the main body. In conjunction with selecting a base code rate 418, the PPDU encoder 320 selects a base code block size (e.g., 648). That is, the PPDU encoder 320 preferably determines the optimal combination of longest block size and lowest rate. In some implementations (e.g., for very short PPDUs where longer code blocks exceed the required transmission length), the PPDU encoder 320 may provide variable FEC code block sizes in the packet body. Such a determination may be performed via iteration, look-up table, among other mechanisms.

With regard to the number of codewords in the tail sequence 428, the PPDU encoder 320 may also provide variable FEC code block sizes. For instance, there may not be enough capacity in a frame to transmit all full-length code blocks. Since maximum length code blocks are preferred in the main portion of the packet frame, adaptations to fit an integral number of maximum sized blocks to the frame are preferably implemented in the tail sequence. In such circumstances, the PPDU encoder 324 may utilize one or more shorter code blocks at the end of the frame (i.e., tail sequence) to achieve a best fit for blocks in the frame while minimizing excess fill bits and optimizing the codeword length. By repeating some of the bits (as compared to utilizing fill or useless bits), the decoder 330 has the option to use the bits or not. Repeating the bits provides for more reliable decoding. The PPDU encoder 320 provides length adaptation in the tail sequence in an effort to achieve the performance expected with longer length blocks in the main body while minimizing the amount of symbols transmitted, and in particular, the amount of fill bits transmitted. Accordingly, the PPDU encoder 320 minimizes the amount of transmission power consumed and the amount of air-time, the latter which enables communication by other users in the remaining (off-air) time frame.

In short, the PPDU encoder 320 can select any available code rate that is lower than or equal to the target code rate 408, since the coding system 300 enables transmission of data at a lower code rate in the same amount of time as the target code rate. Thus, the PPDU encoder 320 is configured to adapt the code rate to produce a new base code rate and structure that is defined in terms of the codewords across all the OFDM symbols that are optimized for performance with a minimum number of wasted bits. The PPDU encoder 320 packs the codewords into the transmission frame and decides what rate to use and how many bits to use per code block.

In general, block codes can be constructed such that a fixed number of information bits combined with a fixed number of parity bits are systematic to form the code block. The rate of the code is simply the number of information bits divided by the total block size. The code is more powerful if there are more parity bits per information bit in that block. The rate of the code is determined by how many information bits are present relative to the number of parity bits. Instead of processing one long code block, the packet can be separated into smaller pieces. Coded blocks are constructed and mapped to transmission frames used in packets. The length of the payload of the data that is to be sent on each packet and the MCS is variable and can vary over a wide range. There may be an arbitrary number of coded blocks that are constrained by the basic structure of the code and those are to be mapped efficiently into the transmission frame to minimize the amount of excess non-data bits that are needed to fill out the frame.

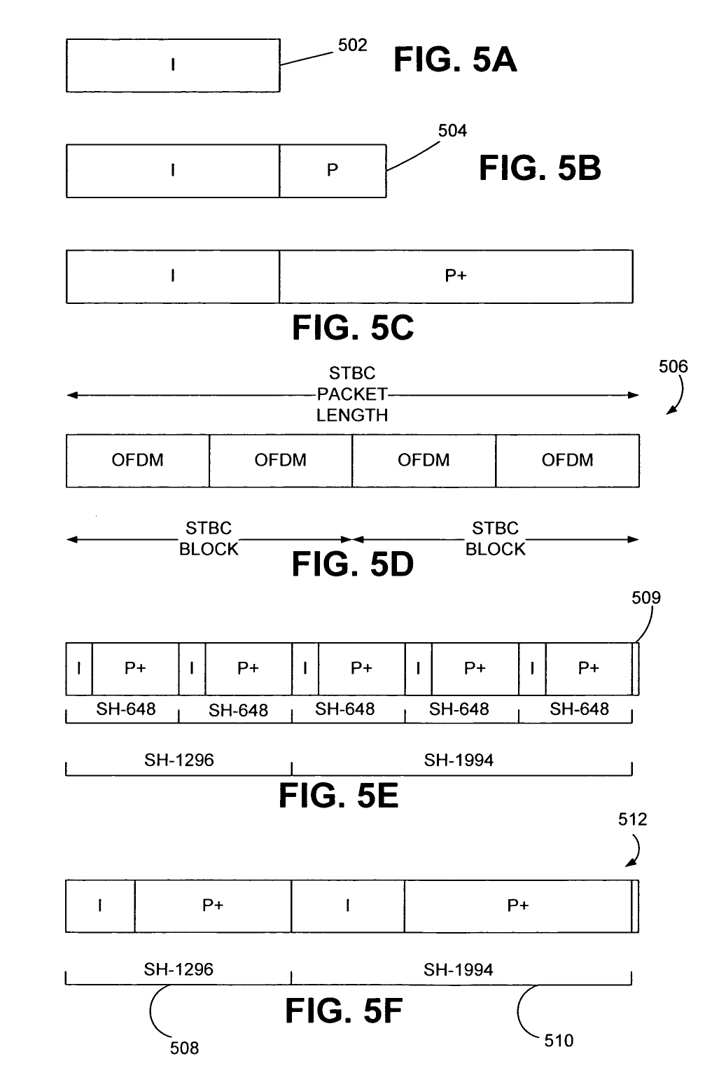

Discussion is now directed to an illustration of a fitting process performed by the PPDU encoder 320. FIGS. 5A-5F are block diagrams that illustrate the construction of an exemplary STBC packet (requiring in one embodiment an even number of OFDM symbols), as performed by the PPDU encoder 320 shown in FIG. 4. FIG. 5A shows payload data 502 comprising information bits to be transmitted. FIG. 5B shows the application of parity bits (P) 504 to the payload data 502. P represents the number of parity bits required, theoretically, to encode the I information bits at a coding rate. For instance, the encoder 320 receives information (e.g., target code rate 408) from the MAC requiring a coding rate, R, say of ⅔. The PPDU encoder 320 is to theoretically construct a code block in a manner such that ⅔ of the final code block is payload data 502 and the remaining ⅓ are parity bits 504 used in the coding process.

Referring to FIG. 5C, shown are the information bits of FIGS. 5A and 5B with P+ parity bits. The P+ represents the minimum number of parity bits (m) available in the available codeblock sizes that support the encoding of I bits at a rate=<⅔. Since the available codeblock size is larger than required for 1 bits, only m+I bits need to be transmitted for this block instead of n bits (e.g. the codeblock is “shortened” and effectively encoded at lower rate).

FIG. 5D shows the code structure of FIG. 5F (described below) mapped into a modulated symbol frame 506 of OFDM symbols. That is, modulated symbol frame 506 comprises an STBC packet comprised of a minimum data frame length of 4 OFDM symbols. FIGS. 5E-5F illustrate a fitting and merging process performed by the PPDU encoder 320 for the STBC packet 506 based on the information and parity bits shown in FIG. 5C. As shown in FIG. 5E, the PPDU encoder 320 uses 648 bit sized blocks. Each block comprises information (I) and parity (P+) bits. The “sh” prefix represents shortening. The PPDU encoder 320 then merges these 648 bit coded blocks in groups to form a string of codewords comprised of the longest possible code blocks, as illustrated by the coded structure 512 in FIG. 5F. In other words, preferably there are as many 1944-bit sized shortened code blocks as possible. Thus, the PPDU encoder 320 optimizes the packet structure based on 648 bit block sizes, and then combines the 648 bit blocks into groups of one, two, and three to determine what fits, resulting in a maximum codeword length, best fit frame construction.

A shortening algorithm performed by the PPDU encoder 320 constructs the code blocks so that at the end of transmission the number of iterations can be reduced without compromising the performance of the decoder. In general, the PPDU encoder 320 can arrange the codeblocks in any way with nearly the same average coding performance. The PPDU encoder 320 tries to minimize the number of blocks and iterations to be decoded after the last symbols. The asymptotic code rates are the basic rates of the codes designed into the system, assuming a full code block with no shortening. The effect of codeword shortening is to reduce the effective coded rate of the transmission.

For a given rate, it is preferred that the PHY not use significantly more OFDM symbols than required to transmit the encoded data at that rate. Thus, once the OFDM frame size of a packet is determined, if there are not enough coded bits to fill the frame, then the PPDU encoder 320 can use code block shortening as a mechanism for optimizing the effective rate for a given OFDM frame capacity. The number of shortening bits and fill bits feasible depends, at least in part, on the codeword construction of the packet and the number of bytes to be transmitted in the payload. The tradeoff for LDPC codes is not without challenges because the codeword length is not the same as the OFDM symbol size, and the latter may vary over a wide range depending on transmission mode. When the payload exactly fits an integral number of full code blocks, then the effective coded rate asymptotically approaches the target rate of R.

The shortening technique reduces the effective rate of the code so the code blocks decode with less iterations. This shortening is particularly beneficial at the end of transmission where decoding time is constrained. The reliability (bit error rate (BER) performance) of decoding any one codeword improves with the number of iterations used in the decoding process. In order that the BER be balanced for all codewords in the packet, the number of iterations should be the same for all codewords, assuming that these codewords all utilize the same construction rules. Typically, it is preferable to have several (e.g. 6-12) decoding iterations per decoded LDPC codeword to achieve reasonable BER performance. However, if a particular codeword is shortened, fewer iterations are used to decode, with the same reliability as for a full non-shortened codeword.

In shortened codewords the unused information bits are effectively pre-defined, but not transmitted. Thus, the parity bits are calculated on the reduced number of information bits plus predefined bits. Only the reduced block of information bits and parity bits are transmitted, though not limited to such mechanisms. The decoder 330 knows this scheme a priori and inserts the pre-defined missing bits prior to decoding, thus improving the decoding likelihoods for the remaining bits that were transmitted and subject to noise corruption. Shortening has an advantage of requiring fewer decoding iterations for a given level of decoding performance.

The bit error rate performance of shortened code blocks increases as a function of the amount of shortening (also correlated to the effective reduction in coded rate in the transmission). Therefore, the number of iterations required for decoding a shortened codeword can be reduced and the same error rate performance can be achieved as for non-shortened codewords. This relationship is not linear, and is exploited in order to reduce the number of iterations required in shortened “tail sequence” blocks in the packet—particularly for those codewords that must still be decoded at the end of transmission.

For example, with a relatively small amount of codeword shortening, the number of iterations required for a target level of BER performance can be cut in half—thus allowing the decoder 330 to finish decoding in half the time. The decoder 330, which is a very complex logic circuit or device, can run at high speed. The complexity is related to the parallel functionality, running parallel computations to decode code blocks for high data rates. In addition, when the end of the packet is reached, the remaining section at the end of the transmission is decoded in a constrained amount of time. A subsequent packet can be received very soon after the previous one is finished. These methods implemented by the PPDU encoder 320 simplify the decoder 330, increasing the decoding performance at the end of transmission, thereby reducing decoder computation and/or latency

Also, the methods employed at the PPDU encoder 320 provide a further benefit. There is generally an average decoding rate which occurs during the packet and a peak decoding rate that is required to satisfy the end of transmission constraint. The peak decoding latency, or the peak speed to average speed ratio, can be reduced to decrease the decoder latency.

Further, IEEE 802.11 radios have different modes of operation with different modulations and coding rates, which result in different frame sizes and different symbol sizes. In addition, there are multiple symbols or frames that are transmitted simultaneously. Exemplary embodiments of the coding system 300 yield an optimum construction for these modes. By reducing the effective coding rate at the end of the packet, the iterations necessary to decode the packet are reduced and the peak speed of the decoder 330 relative to decoding the last symbol can remain close to the average speed.

One goal for exemplary embodiments of the coding system 300 is for shortening to be applicable for each packet, independent of the structure and mode of the packet, for both the PPDU encoder 320 and decoder 330 with reduced amount of processing, so that the parameters that are required to construct these packets can be generated at the time of transmission. The packets can also be generated exactly the same way at the time of reception. In this manner, the decoder 330 performs the same algorithm that the PPDU encoder 320 does. For instance, the PPDU encoding parameters are computed at both the transmitter device 302 and receiver device 304 from input parameters such as length and MCS information, so the receiver device 304 can utilize the same coded block parameters and frame structure as embedded in the transmitted signal. Thus, the receiver device 304 knows what is coming in, in terms of structure, and it can adjust the decoder 330 to handle that particular structure. Each packet and each mode can be different for subsequent transmissions.]

To decrease the decoding latency, the LDPC codewords are structured such that the last LDPC code block requires substantially fewer iterations for adequate decoding reliability. The last block in a packet is forced to be a shortened codeword. The LDPC codeword and the shortened codeword sizes are constructed to fit into an integral number of OFDM symbols for each modulation mode such that a minimum (or zero in many cases) number of pad bits are required to encode the packet.

With continued reference to FIGS. 5E and 5F, note bit region 509, which is referred to as a zero padding or fill bit region. PSDUs are generally encoded with zero pad bits or fill bits added as needed so that an integral number of code blocks and an integral number of OFDM symbols can be transmitted. With the relatively large block size required for LDPC codes (at least 2000 bits) the effective rate loss due to zero padding can be substantial, especially for shorter packets (e.g., less than 8 Kbyte data bits). For example, a 1 kilobyte block could experience a 20% loss in effective rate or more depending on transmission mode, which negatively impacts through-put performance. Decoding latency and, hence, complexity can be reduced if the maximum number of required decoding iterations can be reduced.

The zero padding region 509 can be filled with zero or useless bits in some embodiments, or replicated bits in some embodiments. Replicated bits refer to one or more bits from a previously transmitted codeword. With replicated bits, the decoder 330 has the option of either ignoring the replicated bits or using the bits to strengthen the reception of those particular bits. That is, if selected bits are received twice, the decoder's approximation of those bits can be combined to improve the reliability of the transmission (e.g., noise corruption can be averaged out in the decoding process since noise affects each transmission differently).

One having ordinary skill in the art would understand in the context of this disclosure that FIGS. 5A-5F comprise a simple, non-limiting example of general operation of the PPDU encoder 320 implementing an exemplary fitting process. That is, FIGS. 5A-5F illustrate some general functions implemented by the PPDU encoder 320 to arrive at an optimized frame with an optimized main body 508 and tail sequence 510. Further, one having ordinary skill in the art would understand that other sub-optimum frame constructs are within the scope of the preferred embodiments. For instance, in some embodiments, the PPDU encoder 320 may prepare for transmission five (5) 648-bit codewords, or in some embodiments, prepare for transmission the 1944 block size first and the 1296 block size second (e.g., the latter resulting in the decoding of two codewords, requiring a faster decode operation than if there is a single codeword). The block size inserted at the tail end 510 is generally determined based on minimizing the number of codewords that are to be decoded at the end of transmission. For instance, once a frame is constructed and received at a decoder 330, decoding does not commence until the last codeword is available for processing. Thus, one goal is to organize the frame construction to decode one codeword at the end of transmission, rather than two or more codewords. In some embodiments, it is preferable to decode one long codeword at the end of transmission rather than two shorter codewords.

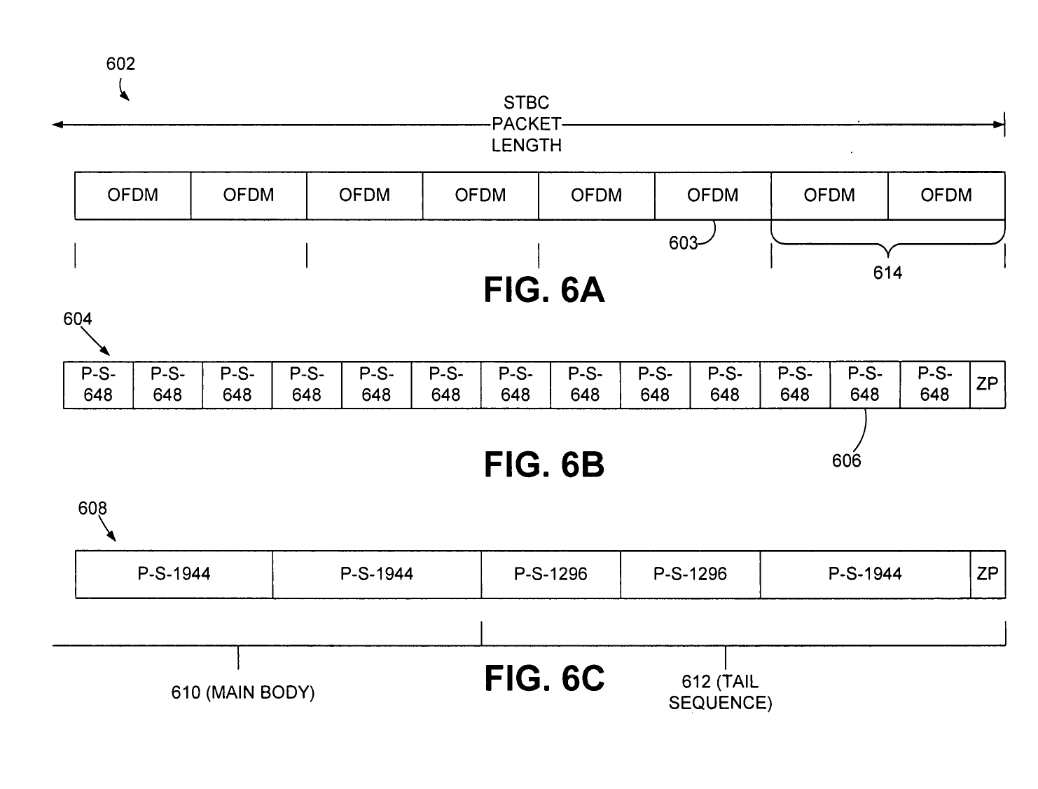

FIGS. 6A-6C are block diagrams that expand on the structures illustrated in FIGS. 5A-5E. Packet 602 of FIG. 6A shows an STBC packet having a plurality of OFDM symbols 603. Coded block structure 604 of FIG. 6B comprises the packet 602 broken down into minimum block sizes. In particular, the blocks shown comprise punctured and shortened (p-s) 648 bit blocks 606. In punctured codewords, which was not shown in FIGS. 5A-5F, some of the encoded bits are systematically not transmitted. The decoder 330 fills in these missing or “erased” bits in the decoding process. Puncturing effectively decreases the ratio of parity bits to transmitted bits and thus increases the effective code rate. Since puncturing may decrease the decoding reliability, shortening is often preferred as a means of fitting the coded blocks to shorter frames. However, both techniques are viable means of tailoring the coded block sizes to available frame size. That is, shortening is preferred on the basis of performance, but sometimes a limited amount of puncturing may be required to get an efficient fit. Puncturing may reduce performance slightly, and is thus is generally limited in use as needed. For example, if the absolute minimum number of OFDM symbols is required in a transmission, puncturing is useful to achieve a best fit within this constraint. In one embodiment, puncturing and shortening are implemented identically or substantially identically (e.g., same shortening and puncturing ratios when fitted and merged into longer blocks) for each codeword to maintain consistent performance over the entire transmission. The fitting and merging of the blocks is illustrated by the resulting structure 608 shown in FIG. 6C, which comprises main body 610 and tail sequence 612.

Note that the last epoch 614 comprises a modulated block of data in the form of a pair of STBC encoded OFDM symbols. In one embodiment, the last epoch 614 is to be demodulated first before decoding can commence. The amount of codewords or code bits that are to be decoded at the end of transmission is based on the amount of code blocks that overlap the last epoch 614. Accordingly, the PPDU encoder 320 organizes the tail sequence 612 to reduce the amount of overlapping code blocks to provide for optimal tail decoding by the decoder 330. Further, the OFDM epoch sizes are determined based on known system design parameters, and can be arbitrary in some embodiments. For instance, the OFDM epoch size may be based on the type of modulation (e.g., 64QAM, QPSK, etc.), the frequency band of operation (e.g., 20 MHz, 40 MHz, etc.), and/or the number of spatial streams transmitted (e.g., 1, 2, etc.), etc.

Note that the above described process of fitting and merging corresponding to a packet structure may vary from packet to packet as packets are being transmitted. That is, with each packet that is being transmitted, the PPDU encoder 320 performs this optimization of the frame construction and code construction on a packet-by-packet basis. In some embodiments, less than a packet-by-packet implementation may be used. The PPDU encoding parameters are preferably computed quickly prior to LDPCC encoding or decoding the transmission with the PPDU encoder 320 (or decoder 330).

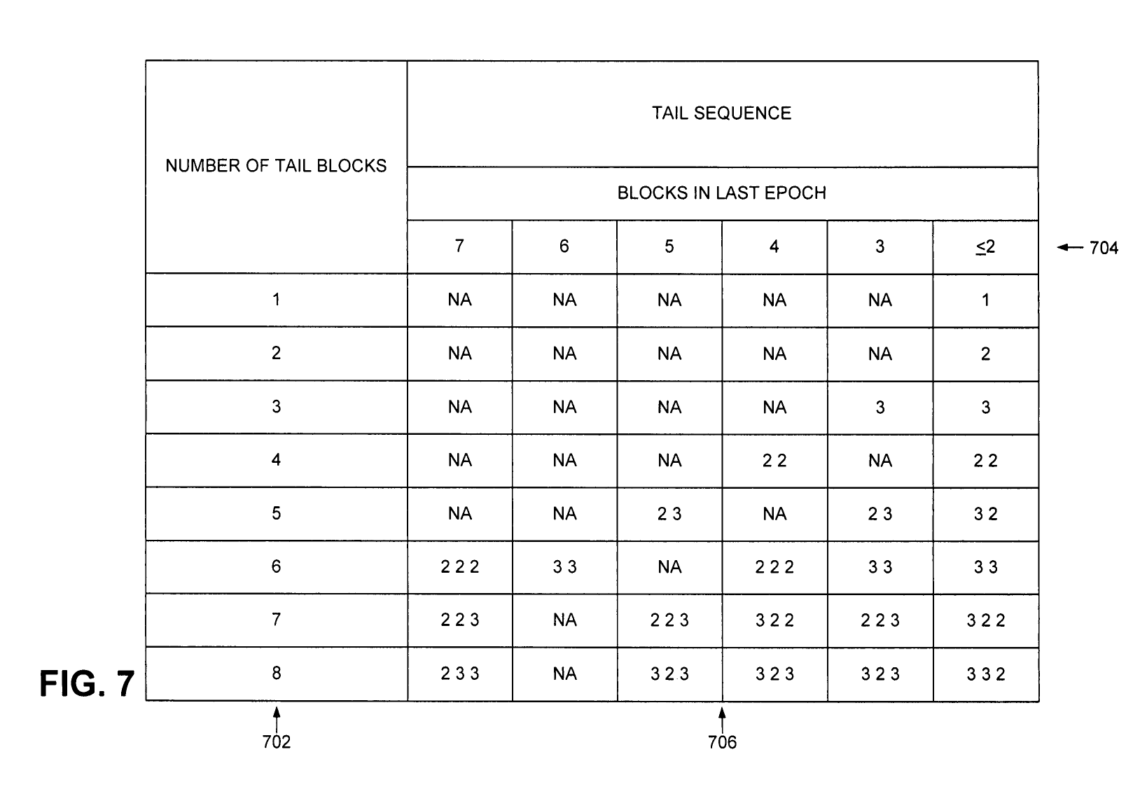

FIG. 7 is a schematic diagram that illustrates how a lookup table 710 for tail sequence selection may be configured in memory of the PPDU encoder 320. In other words, FIG. 7 illustrates one example of how to organize the code blocks in a last OFDM epoch to optimize tail sequence decoding. Note that other mechanisms or data structures may be employed, such as iterative-type processing. Column 702 comprises the number of tail blocks. Row 704 comprises blocks in the last epoch (i.e., illustrating the overlap), and column 706 comprises selectable options of tail sequences for the given number of tail blocks and overlap. In 802.11 n draft standard compliant systems, the maximum number of blocks in the last epoch comprises eight 648-bit blocks. The tail sequences in column 706 are represented with one to three digits. For instance, in the sequence “233,” “2” refers to the 1296 bit size code block and “3” refers to the 1944 bit size code block. “1” would refer to a 648 bit size code blocks. Thus, the tail sequences provided in this table represent one exemplary recipe for merging blocks in the tail sequence.

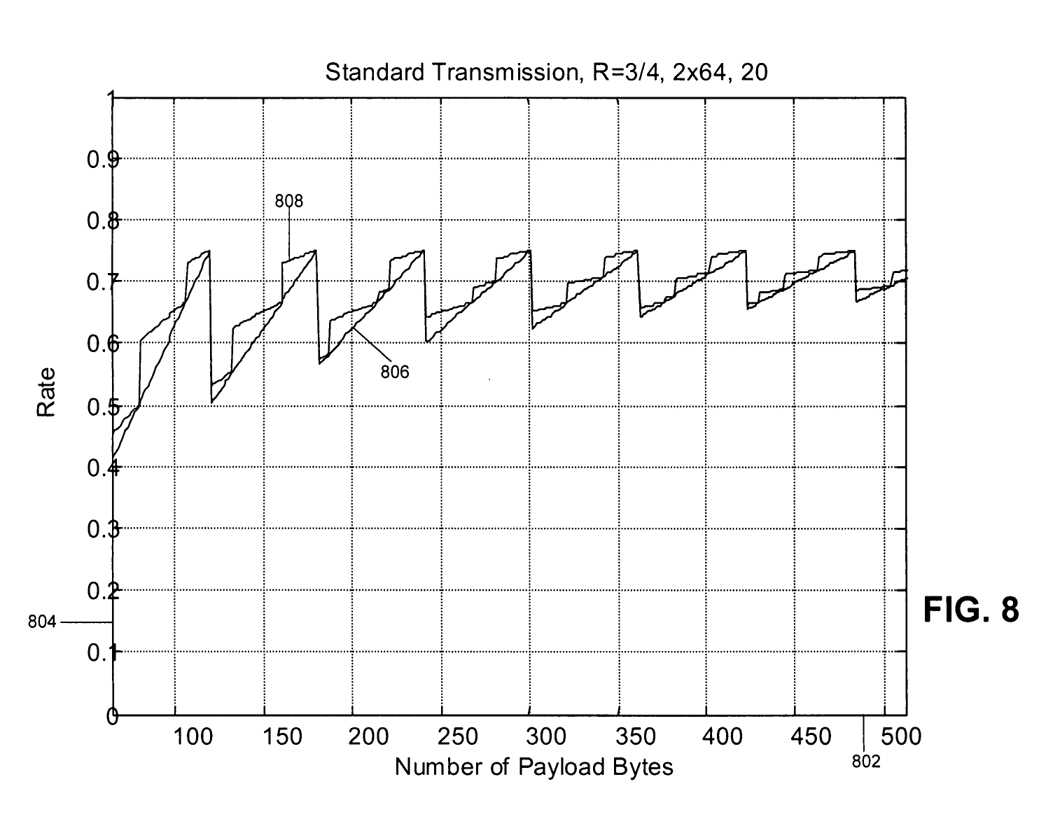

FIG. 8 is a schematic diagram that illustrates an exemplary simulated output of the PPDU encoder 320 based on a targeted rate (R) of ¾ or 0.75, 2-stream 64QAM modulation, and 20 MHz operation. The x-axis 802 comprises the number of payload bytes and the y-axis 804 comprises the effective rate. Line 806 represents the absolute minimum transmission rate that can be achieved with a given OFDM frame capacity for the targeted rate when using an ideal code (i.e., one that has a block length perfectly matched to the payload). As shown, as the number of payload bytes to be transmitted is increased, at certain points (e.g., where line 806 reaches a rate of 0.75), there is an exact fit where actual transmission is at a rate of ¾ or 0.75. That is, there exists no fill bits at these points of transmission, but instead, every bit is a coded bit that is coded at the targeted rate. Line 808 represents the performance actually achieved by the PPDU encoder 320 under the constraints of the three block sizes. Note that there exists a closer approximation to targeted performance as the number of payload bytes increases. For shorter payloads, it is difficult to fit one codeword into a frame. Thus, in such cases, transmission can be at a lower rate in a same period of time, enabling the benefit of additional performance versus conventional mechanisms of insisting on the targeted rate.

In short, the coding system 300 uses a process of code block size adaptation and codeword shortening to ensure that the end of transmission decoding speed increase can be minimized relative to average speed throughout the packet. Further, codeword shortening also helps the decoding performance throughout the main body of codeblocks; or alternatively, fewer iterations can be used to conserve power. In general, the decoder hardware complexity (logic parallelism) is largely determined by the peak computation per unit time required at the end of the packet. Thus the area and cost of IC decoder hardware is generally driven by the end-of-packet decoding speed.

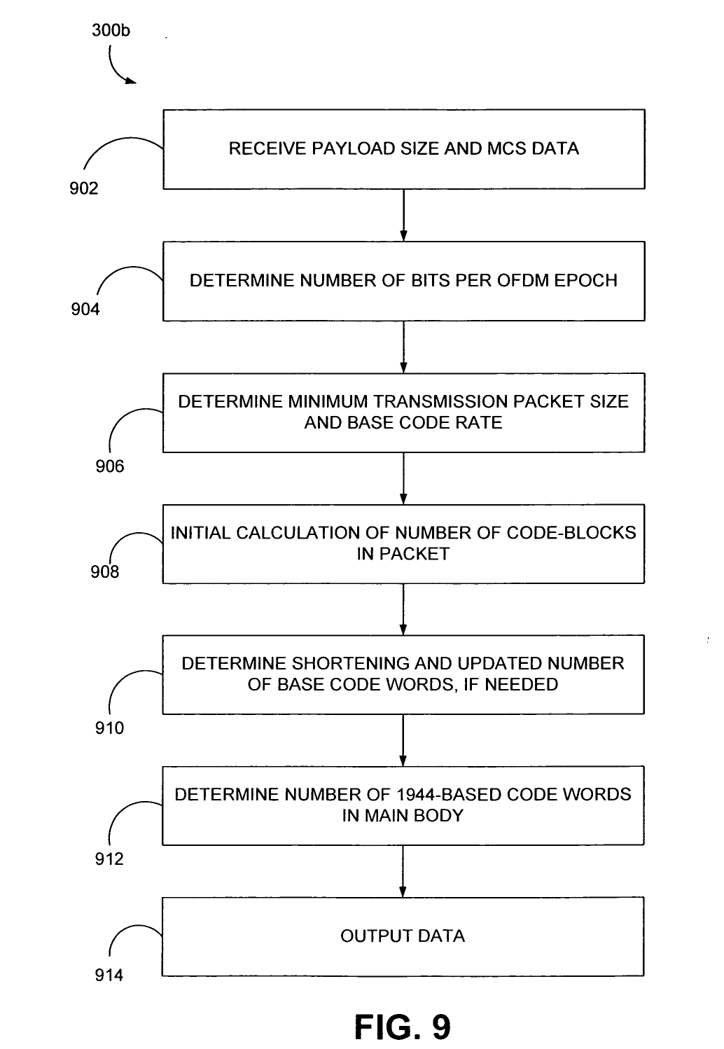

In view of the above description, it would be appreciated that a coding method 300b, as illustrated in FIG. 9, comprises receiving payload size and MCS data (902). Such information includes the parameters provided by the MAC. The coding method 300b further comprises determining the number of bits per OFDM epoch (904), determining the minimum transmission packet size and base code rate that can be supported in the determined packet size (906), performing an initial calculation of the number of code blocks in a packet (908), determining the shortening and updating the number of base codewords if needed (910), determining the number of 1944-bit based codewords in the main body (912), determining an optimum tail sequencing (e.g., number, size, and ordering) of codeword sizes to be used at the end of the packet (913), and outputting the adapted codeword lengths and shortening and puncturing parameters (914).

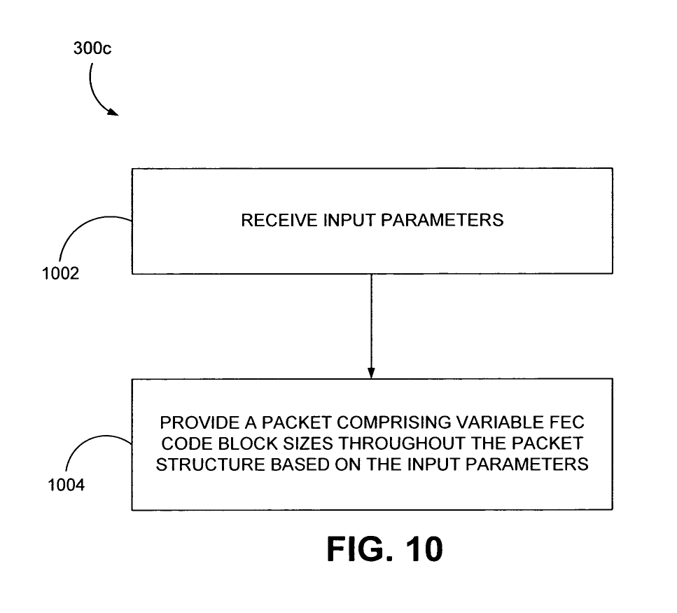

In view of the above description, it would be appreciated that a coding method 300b, as illustrated in FIG. 10, comprises receiving input parameters (1002) and providing a packet comprising variable FEC code block sizes throughout the packet structure based on the input parameters (1004).

The flow diagram of FIGS. 9 and 10 show the architecture, functionality, and operation of a possible implementation of the coding methods 300b and 300c corresponding to coding system 300. In this regard, each block represents a module, segment, or portion of code, which may comprises one or more executable instructions for implementing the specified logical function(s). It should also be noted that in some alternative implementations, the functions noted in the blocks may occur out of the order noted in FIGS. 9 and 10. For example, two blocks shown in succession in FIGS. 9 and 10 may in fact be executed substantially concurrently or the blocks may sometimes be executed in the reverse order, depending upon the functionality involved, as will be further clarified hereinbelow.

Note that in some embodiments, in composing and encoding each packet as a string of an integral number of OFDM symbols, the MAC can assist in aggregating data into bundles that encode with the best coded transmission performance.

It should be emphasized that the above-described embodiments, particularly, any “preferred” embodiments, are merely possible examples of implementations, merely set forth for a clear understanding of the disclosed principles of the various embodiments. Many variations and modifications may be made to the above-described embodiment(s) without departing substantially from the spirit and principles of the invention. All such modifications and variations are intended to be included herein within the scope of this disclosure and protected by the following claims.

What is claimed:

1. A coding method, comprising:
receiving input parameters; and
providing a packet comprising variable forward error-correction (FEC) code block sizes throughout the packet structure based on the input parameters.

2. The method of claim 1, wherein receiving the input parameters comprises receiving a modulation rate, packet length, and transmission mode information.

3. The method of claim 1, wherein receiving the input parameters comprises receiving information corresponding to one or a combination of payload data length, modulation technique, target code rate, number of streams, frequency band, and space-time block coding scheme.

4. The method of claim 1, wherein providing the packet comprising variable forward error-correction (FEC) code block sizes comprises providing the packet comprising low density parity check codes.

5. The method of claim 1, wherein the variable FEC code block sizes correspond to wireless LAN specifications.

6. The method of claim 1, wherein the variable FEC code block sizes correspond to 802.11 specifications.

7. The method of claim 6, wherein the 802.11 specifications comprise a 802.1 In draft standard.

8. The method of claim 1, wherein providing the packet comprising variable forward error-correction (FEC) code block sizes comprises providing the variable FEC code block sizes in a tail sequence of the packet structure.

9. The method of claim 1, wherein providing the packet comprising variable forward error-correction (FEC) code block sizes comprises providing the variable FEC code block sizes in a main body of the packet structure.

10. The method of claim 1, further comprising transmitting the packet.

11. The method of claim 1, further comprising receiving the packet.

12. The method of claim 1, further comprising decoding the packet.

13. A method of computing encoding parameters, the method comprising:
determining a number of bits per orthogonal frequency division multiplexing (OFDM) epoch corresponding to a packet and packet size;
determining a minimum transmission packet size and base code rate that can be supported in the determined packet size;
performing an initial calculation of a number of code blocks to be used in the packet;
determining a shortening mechanism and updating a number of base codewords to be used in the packet if needed;
determining a number of largest size based codewords in a main body to be used in the packet;
determining an optimum tail sequencing of codeword sizes to be used at the end of the packet; and
outputting adapted codeword lengths and shortening and puncturing parameters corresponding to the packet.

14. The method of claim 13, wherein the method is implemented at a physical layer convergence procedure, protocol data unit (PPDU) encoder.

15. The method of claim 13, wherein the method is implemented at a decoder.

16. A coding system, comprising:
encoding logic configured to receive input parameters, and provide a packet comprising variable forward error-correction (FEC) code block sizes throughout the packet structure based on the input parameters.

17. The system of claim 16, wherein the encoding logic comprises a physical layer convergence procedure, protocol data unit (PPDU) encoder.

18. The system of claim 16, wherein the input parameters comprises a modulation rate, packet length, and transmission mode information.

19. The system of claim 16, wherein the input parameters comprises one or a combination of payload data length, modulation technique, target code rate, number of streams, frequency band, and space-time block coding scheme.

20. The system of claim 16, wherein the packet comprises low density parity check codes.

21. The system of claim 16, further comprising decoding logic configured to decode the packet.

22. The system of claim 21, wherein the encoding logic and the decoding logic is further configured to:
determine a number of bits per orthogonal frequency division multiplexing (OFDM) epoch corresponding to the packet and the packet size;
determine a minimum transmission packet size and base code rate that can be supported in the determined packet size;
perform an initial calculation of a number of code blocks to be used in the packet;
determine a shortening mechanism and update a number of base codewords to be used in the packet if needed;
determine a number of largest size based codewords in a main body to be used in the packet;
determining an optimum tail sequencing of codeword sizes to be used at the end of the packet; and output adapted codeword lengths and shortening and puncturing parameters corresponding to the packet.

23. The system of claim 21, wherein the encoding logic and the decoding logic comprise hardware, software, or a combination of hardware and software.

24. The system of claim 21, wherein the encoding logic and the decoding logic are configured in a communications device.

25. The system of claim 16, wherein the encoding logic is configured to provide the variable FEC code block sizes in a tail sequence of the packet structure.

26. The system of claim 16, wherein the encoding logic is configured to provide the variable FEC code block sizes in a main body of the packet structure.

27. A coding system, comprising:
means for receiving input parameters; and
means for providing a packet comprising variable forward error-correction (FEC) code block sizes throughout the packet structure based on the input parameters.

28. The system of claim 27, wherein the means for receiving and providing comprise a physical layer convergence procedure, protocol data unit (PPDU) encoder.

29. The system of claim 27, further comprising means for decoding the packet
